(19) United States
(12) Patent Application Publication
(10) Pub. No.: US 2006/0072134 A1
(43) Pub. Date: Apr. 6, 2006

(54) Image forming apparatus and method

(75) Inventors: Hiroki Umezawa, Shizuoka-ken (JP); Sunao Tabata, Shizuoka-ken (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/079,239

(22) Filed: Mar. 15, 2005

(30) Foreign Application Priority Data
Oct. 1, 2004 (JP) 2004-290057

(51) Int. Cl. G03F 3/08

(52) U.S. Cl. 358/1.9; 358/518

(57) ABSTRACT

An image processing apparatus op the present invention includes inputting means for inputting document data, rendering means for generating raster image data from the input document data, color-conversion-parameter storing means for storing a color conversion parameter, color-conversion processing means for performing color conversion on the raster image data in accordance with the color conversion parameter, and outputting means for outputting the raster image data color-converted by the color-conversion processing means. The image processing apparatus further includes reading means for reading a color image to generate read raster image data; displaying means for displaying the raster image data generated by the rendering means and the read raster image data; and color adjusting means for adjusting color of the output raster image data by modifying the color conversion parameter, with color of a portion designated on a screen displayed by the displaying means being color to be modified.

### BACKGROUND OF THE INVENTION

1. Technical Field of the Invention

The present invention relates to image processing apparatuses and image processing methods. More specifically, the present invention relates to an image processing apparatus and an image processing apparatus which allow easy color adjustment of image data.

2. Related Art

In recent years, with the widespread colorization of various types of document creation software application software, such as word processing software, spreadsheet software, and drawing software, demands for color printing are increasing.

When color printing is performed using color-capable document-creation application software, the resulting document may be printed in color that is not desired by the user. In particular, when a corporate mark (logo mark) or the like, for which accurate color expression is significant, is printed, it is often the case that color expression desired by the user and actually printed color are slightly different from each other.

Such inconvenience results from the design of color conversion parameters for printers. Although color conversion parameters for printers are essentially designed to print accurate color for various types of images, such as characters, graphics, and nature images, the color conversion parameters are finely adjusted so that average users feel satisfied with color when each type of image is printed.

For example, in many cases, the color conversion parameters are finely adjusted so as to provide slightly bright color or slightly high contrast color so that average users feel satisfied with resulting color. Consequently, when a logo mark, which requires accurate color expression, is printed, the color of the print slightly deviates from the intended color.

Even when color conversion parameters are designed so as to print accurate color, it is difficult to create color conversion parameters so that all input colors can be accurately printed. Thus, color error occurs partially. Since the colors of corporate logos are different from one another, a considerable number of colors exist for the corporate logos. Thus, even when the corporate mark of a certain company can be printed in accurate color, the corporate mark of another company may encounter color deviation.

In addition, since a certain level of difference in printed color exists among individual printers, printing is not always be performed in identical color even when the same color conversion parameter preset in the printers is used.

The above description has been given in the context of the color of corporate marks by way of example; however, even for representations other than corporate marks, users may not be satisfied because of individuals' color preferences. As described above, in many cases, color conversion parameters are designed so that average users are satisfied with resulting color. However, color preferences vary depending on individual users. Thus, for example, even when a typical red character is printed using a color conversion parameter preset in a printer, some users are not satisfied with the printed red color.

As a measure for such inconvenience, color adjustment processing has conventionally been available. The color adjustment processing modifies, for example, a color conversion parameter stored in a printer so that desired color is printed.

The operation of known color adjustment processing will be described with reference to FIG. 11.

A color printer 1600 includes outputting means for printing image data and color-conversion-parameter storing means 1620 for storing color conversion parameters.

For example, color-adjustment application software installed on a personal computer that is provided externally to the color printer 1600 is executed to perform the color adjustment processing.

The color-adjustment application software includes color-adjustment processing means 1610 and color-adjustment standard image data 1630. The color-adjustment standard image data 1630 is typically image data that contains multiple different color patches prepared in advance.

The color-adjustment processing means 1610 reads preset color conversion parameters from the color printer 1600.

Subsequently, the user selects a color patch having color that is the closest to color to which he or she desires to adjust, from the color-adjustment standard image data 1630. The selected color patch is displayed on, for example, a display screen of the personal computer, as “pre-modification color”.

Next, the user finely adjusts the displayed pre-modification color to desired color by using an appropriate user interface provided by the color-adjustment processing means 1610. The finely-adjusted color is displayed, as “modified color”, on the display screen, for example, in parallel with the “pre-modification color”. The fine adjustment is performed by finely adjusting a color adjustment parameter loaded from the color printer 1600.

When the “modified color” is adjusted to color that satisfies the user, the user stores the color conversion parameter, modified in association with the “modified color”, from the color-adjustment processing means 1610 onto the color printer 1620. Subsequently, even when image data corresponding to the “pre-modification color” is input to the color printer 1620, the “modified color” is printed by the outputting means in accordance with the modified color conversion parameter.

However, the known color adjustment processing described above has some problems.

A first problem is that the color types of color patches of the color-adjustment standard image data 1630 pre-contained in the color-adjustment application software are limited. Thus, the color-adjustment standard image data 1630 does not necessarily contain color to which the user desires to adjust.

Thus, when the color-adjustment standard image data 1630 does not contain color to which the user desires to adjust, the user needs to newly create the desired color and add it to the color-adjustment standard image data 1630.

In generally, when the user adds color to a document to be created, he or she selects color that he or she desires to use, from a group of colors provided by corresponding document creation application software, in many cases. In such cases, the user does not particularly aware of the specific numeric values of the color that the user selects, for example, numeric values: red=255, green=128, and blue=128.

However, when the user attempts to create new color-adjustment standard image data 1630 on known color-adjustment application software, those specific values of color are required. Consequently, when selecting desired color from the group of colors, the user needs to find the specific numeric values of the selected color and create color-adjustment standard image data 1630 by using the numeric values. Thus, a considerable amount of work is required.

Also, an approach in that color-adjusting application software reads document data to which color is added by the user and the colored image data is converted into the format of the color-adjustment standard image data 1630 is possible in theory. The color-adjustment standard image data 1630 generally has a raster data format, such as the TIFF (tagged image file format). Various formats are available for image data contained in documents created by users, and the format of each piece of image data depends on the type of document-creation application software used and is defined by, for example, word-processing, spreadsheet, or graphics application software. Thus, the user needs to prepare many types of converters for converting many types of formats into the format of the color-adjustment standard image data 1630, for example, the TIFF. Such preparation is significantly complicated for the user, and thus the approach described above would not be practical.

A second problem is that designating the type of color conversion parameter is complicated.

In general, multiple types of color conversion parameters are stored by the color-conversion-parameter storing means 1620 included in the color printer 1600. For example, different types of objects, such as a character, graphics, and nature image, exist in document data input to the color printer 1600. In order to optimally express the color of those different types of objects, multiple types of color conversion parameters corresponding to the types of objects are stored. In addition to the types of objects, the types of color conversion parameter increase in accordance with print conditions, such as the type of paper, the printing resolution, and the type of halftone.

It is not easy for the user to identify the type of color conversion parameter that the user attempts to modify out of many types of color conversion parameters, and it is practically impossible to identify the type in some cases.

Patent Document 1 (Japanese Unexamined Patent Application Publication No. 2002-259109) describes a technology in which color information used on application software is obtained, the obtained color information is converted into a page description language, and the density, line width, and so on are changed for each color for transmission to a printer. However, Patent Document 1 does not disclose any technology that overcomes the problems described above.

Patent Document 2 (Japanese Unexamined Patent Application Publication No. 2003-296088) is intended to facilitate the color adjustment of image data, but does not disclose any technology that overcomes the problems described above.

### SUMMARY OF THE INVENTION

The present invention has been made in view of the foregoing situations, and an object of the present invention is to provide an image processing apparatus and an image processing method which are capable of easily adjusting color conversion parameters, regardless of the type of file format in document data for color adjustment.

In order to achieve the foregoing object, an image processing apparatus according to the present invention includes inputting means for inputting document data, rendering means for generating raster image data from the input document data, color-conversion-parameter storing means for storing a color conversion parameter, color-conversion processing means for performing color conversion on the raster image data in accordance with the color conversion parameter, and outputting means for outputting the raster image data color-converted by the color-conversion processing means. The image processing apparatus further includes reading means for reading a color image to generate read raster image data; displaying means for displaying the raster image data generated by the rendering means and the read raster image data; and color adjusting means for adjusting color of the output raster image data by modifying the color conversion parameter, with color of a portion designated on a screen displayed by the displaying means being color to be modified.

In order to achieve the foregoing object, an image processing method according to the present invention includes a step of inputting document data, a step of generating raster image data from the input document data, a step of storing a color conversion parameter, a step of performing color conversion on the raster image data in accordance with the color conversion parameter, and a step of outputting the color-converted raster image data. The image processing method further includes a step of reading a color image to generate read raster image data; a step of displaying the generated raster image data and the read raster image data; and a step of adjusting color of the output raster image data by modifying the color conversion parameter corresponding to the document structure information, with color of a designated portion of the displayed raster image data being color to be modified.

### BRIEF DESCRIPTION OF THE DRAWINGS

FIG. 1 is a block diagram showing an exemplary configuration of an image processing apparatus according to a first embodiment of the present invention;

FIG. 2 is a first view illustrating an exemplary operation of an image processing apparatus according to the present invention;

FIG. 3 is a diagram illustrating the operation of color conversion parameters (a 3D LUT) of the image processing apparatus according to the present invention;

FIG. 4 is a second view illustrating an exemplary operation of the image processing apparatus according to the present invention;

FIG. 5 is a view showing one example of color adjusting means of the image processing apparatus according to the present invention;

FIG. 6 is a block diagram showing an exemplary configuration of an image processing apparatus according to a second embodiment of the present invention;

FIG. 7 is a view illustrating the concept of reducing raster image data in the image processing apparatus according to the present invention;

FIG. 8 is a block diagram showing another exemplary configuration of the image processing apparatus according to the second embodiment of the present invention;

FIG. 9 is a block diagram showing an exemplary configuration of an image processing apparatus according to a third embodiment of the present invention;

FIG. 10 is a block diagram showing an exemplary configuration of an image processing apparatus according to a fourth embodiment of the present invention; and

FIG. 11 is a block diagram illustrating a method for color adjustment according to related art.

### DETAILED DESCRIPTION OF PREFERRED EMBODIMENTS

An image processing apparatus and an image processing method according to embodiments of the present invention will be described with reference to the accompanying drawings.

### (1) First Embodiment

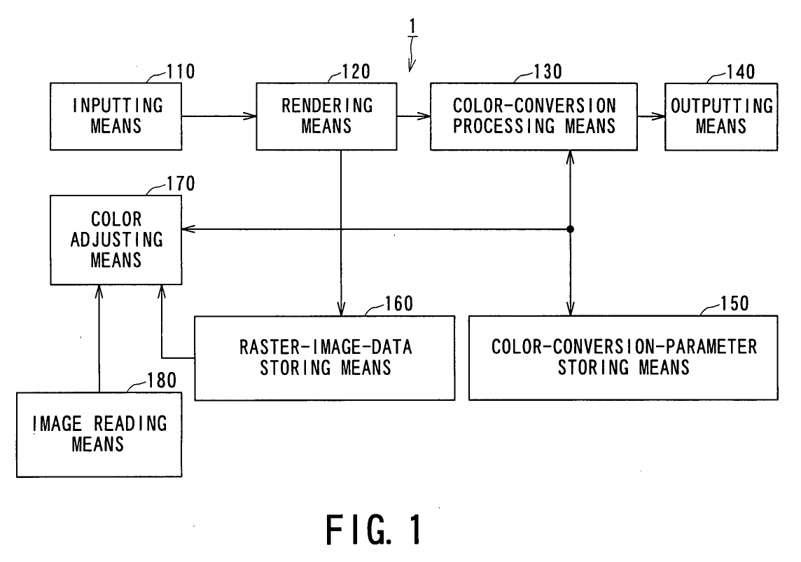

FIG. 1 is a block diagram showing an exemplary configuration of an image processing apparatus 1 according to a first embodiment of the present invention.

The image processing apparatus 1 includes inputting means 110 for inputting document data, rendering means 120 for generating raster image data from the input document data, color-conversion-parameter storing means 150 for storing a color-conversion parameter, color-conversion processing means 130 for converting the color of the raster image data in accordance with the color conversion parameter, and outputting means 140 for outputting the raster-image data color-converted by the color-conversion processing means 130.

In addition, the image processing apparatus 1 includes raster-image-data storing means 160 for storing the raster image data generated by the rendering means 120 and image reading means 180 (which may be simply referred to “reading means”) for reading a hardcopy document (color images) containing the user's desired color to generate read raster image data. The image processing apparatus 1 further includes color adjusting means 170 for displaying the stored raster image data and the read raster image data, and adjusting the color of the output raster image data, with the color of a designated portion of the displayed raster image data being color to be modified, by modifying the color conversion parameter.

The inputting means 110 is means for inputting document data to the image processing apparatus 1 and may be a communication interface, such as an LAN (local area network), the Internet, an USB (universal serial bus), a telecommunication network, or a dedicated communication line. The inputting means 110 may be wired or wireless.

The inputting means 110 may have a configuration for inputting document data from an external storage medium, such as a CD-ROM or DVD, or may have a configuration for inputting document data from an appropriate internal storage device built into the image processing apparatus 1.

The inputting means 110 may have a configuration for inputting document data from an image generating apparatus, such as a scanner or a digital camera.

The outputting means 140 converts document data processed by the color-conversion processing means 130 into information that can be recognized by human vision, and corresponds to printing means and a display device. An example in which the outputting means corresponds to printing means will be described in the following embodiments, unless otherwise specified.

The inputting means 110 receives document data containing a single page or multiple pages. The document data is often created with typical document creation software, for example, Microsoft Word, Excel, or Adobe Acrobat (registered trademarks). The inputting means 110 receives the document data or document data pre-converted by a printer driver or the like into a PDL (page description language), such as Postscript (registered trademark) or PCL (printer control language).

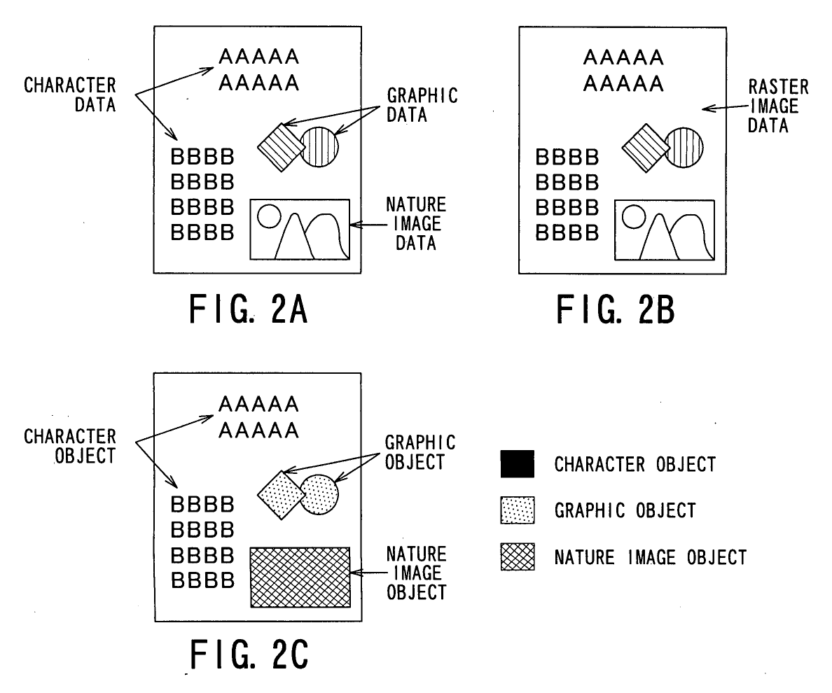

The rendering means 120 converts the input document data into raster image data. As shown in FIG. 2A, data other than raster image data may be contained in the document or page(s) of the input data. That is, character data is non-raster data expressed by, typically, ASCII (American National Standard Code for Information Interchange) and information, such as the color information and size of characters. Graphics data created by the so-called “graphics drawing software” is expressed by non-raster data, i.e., vector data containing shapes, such as straight lines, rectangles, and circles; sizes; positions; and color information. Nature image data may have the format of compressed non-raster data.

FIG. 2B shows a state in which the character data, graphics data, and nature image data are all converted into raster image data.

The color-conversion processing means 130 converts the color of raster image data in accordance with a color conversion parameter. The color conversion parameter can be expressed in a table or a matrix format. For convenience, the following description is given of only a color conversion parameter expressed in a table format, unless otherwise specified. The present invention, however, is not limited to a color conversion parameter expressed in a table format.

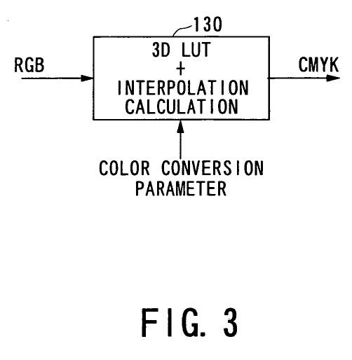

FIG. 3 shows one example of processing performed by the color-conversion processing means 130. In FIG. 3, the color space of input raster image data is an RGB color space expressed by RGB (Red, Green, and Blue) and the color space of raster image data output from the color-conversion processing means 130 is a CMYK color space expressed by CMYK (Cyan, Magenta, Yellow, and Black). Thus, an input value defined by three R, G, and B parameters is color-converted into an output defined by four C, M, Y, and K parameters.

The color-conversion processing means 130 has a three-dimensional lookup table (3D LUT). Data that determines CMYK values into which input RGB values should be converted are pre-stored in the 3D LUT. The data stored in the 3D LUT is one type of color conversion parameters and a color conversion parameter corresponding to the attribute of image data to be color-converted is stored by the color-conversion processing means 130 shown in FIG. 3. That is, a plurality of conversion parameters are generally stored depending on the attribute of image data to be color-converted.

Typically, each of the input R, G, and B has about 256 colors (8 bits). In this case, the number of color types is as large as about 16,700,000, which is not practical for direct use as 3D LUT data in terms of the memory capacity. Accordingly, each axis of R, G, and B is split into multiple axes and CMYK values corresponding to the combinations of RGB values at grid points that are located at the intersections of the split axes are stored, as 3D LUT data, in the 3D LUT.

With the data stored in the 3D LUT in that manner, when a combination of input RGB values exists at a grid point of the 3D LUT, the CMYK values of data located at the grid point of the 3D LUT are output. When a combination of input RGB values does not exist at a grid point of the 3D LUT, multiple grid points (e.g., 8 points) that are immediately adjacent to the input RGB values are extracted and, based on CMYK values of the 3D LUT data which correspond to the extracted grid points, interpolation calculation is performed to output CMYK values corresponding to the input RGB values.

For ease of description, color conversion parameters have been described, by way of example, as directly connecting values in the RGB color space and values in the CMYK color space. The color, however, can be expressed by various color systems.

Examples include color conversion parameters that indirectly connect values in the RGB color space and values in the CMYK color space by using values in the space of CIE (Commission Internationale d'Eclairage: International Commission on Illumination) LAB color system that is device independent and that is highly compatible with human vision. In the CIE LAB color system, the color is expressed by three elements, namely, L*, a*, and b*. L* indicates lightness and a* and b* indicate hue and chromaticness (brightness).

The outputting means 140 is means for printing an image. The outputting means 140 may be of an inkjet system, electrophotographic system, or thermal transfer system but the present invention is not particularly limited to the system.

The color-conversion-parameter storing means 150 includes, for example, a hard disk and a semiconductor memory and stores color conversion parameters used by the color-conversion processing means 130. In the example of color-conversion processing means 130 shown in FIG. 3, a color conversion parameter is stored in the form of a 3D LUT with an RGB input and a CMYK output.

The raster-image-data storing means 160 stores raster image data, which is document data rasterized by the rendering means 120. For example, the raster-image-data storing means 160 stores raster image data shown in FIG. 2B.

In accordance with a user instruction, the color adjusting means 170 modifies a color conversion parameter, stored by the color-conversion-parameter storing means 150, so that color desired by the user is output. When the user performs an operation for color adjustment, the raster image data stored by the raster-image storing means 160 is used.

The operation of the image processing apparatus 1 configured as described above will now be described.

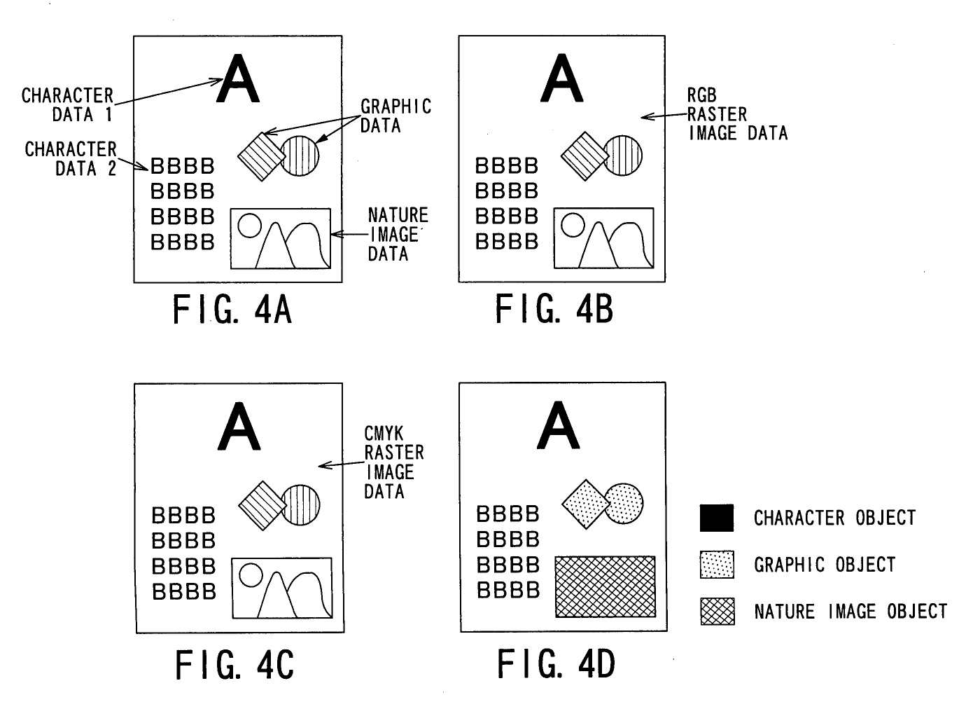

FIG. 4A shows one-page document data that the user has created using typical document creation software. The document data contains character data, vector (graphics) data, and nature image data. The character of document data 1 is, for example, a red character that the user designated using the typical document creation software. The document data is input to the image processing apparatus 1 via the inputting means 110.

Subsequently, the rendering means 120 converts the document data, vector data, and nature image data in the document into RGB raster image data shown in FIG. 4B. The raster image data is input to the color-conversion processing means 130 and is also stored by the raster-image-data storing means 160.

Also, 3D LUT data, which contains color conversion parameters pre-stored by the color-conversion-parameter storing means 150, is contained in the 3D LUT of the color-conversion processing means 130. Based on the 3D LUT, the color-conversion processing means 130 sequentially performs interpolation calculation on RGB values, contained in input RGB raster image data, to convert the RGB values into CMYK values, as required. FIG. 4C shows raster image data converted into CMYK as described above. The raster image data that has been color-converted is printed by the outputting means 140.

When the user sees a printed hard copy, he or she may think that the red of the character of character data 1 is not desired color. In such a case, using the color adjusting means 170, the user can modify the color conversion parameter so that desired red is obtained for the character of character data 1.

An example of color adjustment using the color adjusting means 170 will now be described in more detail.

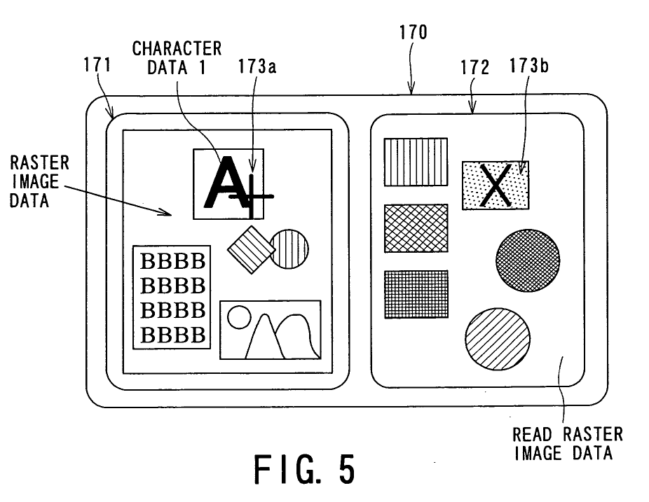

As illustrated in FIG. 5, the color adjusting means 170 has user interfaces, for example, first displaying means 171 (hereinafter referred to as “image displaying means 171”) for displaying raster image data and second displaying means 172 (hereinafter referred to as “read-image displaying means 172”) for displaying read raster image data.

The read raster image data contains a hardcopy color image read by the image reading means 180.

When a hard copy containing the user's desired color exists, the image reading means 180 can read the hardcopy document to provide electronic raster image. Thus, the provision of the image reading means 180 provides an advantage in that the user's color adjustment operation is significantly facilitated.

The image reading means 180 includes, but not particularly limited to, a scanner. In such a case, the image reading means 180 is constituted by electronic reading devices, such as a light source and a CCD sensor; an actuation circuit; an optical system; and so on. In addition, the image reading means 180 may include, for example, a digital camera.

The electronic raster image data generated through the reading of the image reading means 180 is displayed by the read-image displaying means 172 of the color adjusting means 170.

An example of color adjustment using the color adjusting means 170 in the present embodiment will now be described with reference to FIG. 5. As shown in FIG. 5, the color adjusting means 170 has user interfaces, such as the image displaying means and color instructing means.

The color adjusting means 170 has two image displaying means, i.e., the image displaying means 171 and the read-image displaying means 172.

The image data displayed by the image displaying means 171 is the raster image data generated by the rendering means 120. On the other hand, the image data displayed by the read-image displaying means 172 is the read raster image data generated by causing the image reading means 180 to read a hardcopy document containing the user's desired color.

The user uses a pointing device (not shown), such as a mouse, to move a crosshair cursor 173a, which is included in the color instructing means, so as to designate the color of character data 1 in the raster image data displayed by the image displaying means 171, as unwanted color, that is, color that the user desires to modify (i.e., pre-modification color).

The color adjusting means 170 stores the RGB values “R1, G1, and B1” of the color of character data 1.

On the other hand, when the color of character data 1 of a hard copy document contains desired red, the hard copy document is read as read raster image data by the image reading means 180 and is displayed by the read-image displaying means 172.

Next, the user uses the pointing device (not shown), such as a mouse, to move an X-shaped cursor 173b, which is included in the color instructing means, so as to designate a portion containing the user's desired red, the portion existing in the read raster image data displayed by the read-image displaying means 172.

As described above, when a hard copy in the possession of the user contains desired color, desired color can be designated with significant ease. The color adjusting means 170 stores the RGB values “R2, G2, and B2” of red that is the color of the portion designed with the X-shaped cursor 173b.

When the RGB values “R1, G1, and B1” of the color that the user desires to modify and the RGB values “R2, G2, and B2” of desired color are determined by the user's operation described above, a corresponding color conversion parameter is modified in accordance with those RGB values.

The format of the raster image data displayed by the image displaying means 171 has already been converted into a raster data format by the rendering means 120. Thus, the image display means 171 can easily display the RGB raster image data, without a need for a special format converter.

With the operation described above, the RGB values “R1, G1, and B1” of color that the user desires to modify (i.e., pre-modification color) and the RGB values “R2, G2, and B2” of desired color are designated. In accordance with those RGB values, the color adjusting means 170 adjusts a color conversion parameter pre-read from the color-conversion-parameter storing means 150.

Next, a description is given of a specific example of a method for modifying a color conversion parameter, i.e., the 3D LUT.

When color “R1, G1, and B1” before modification exists at a grid point of the 3D LUT, CMYK values “C1, M1, Y1, and K1” before the modification are stored at the grid point. The color adjusting means 170 determines color after the color adjustment, i.e., CMYK values “C2, M2, Y2, and K2” corresponding to desired color “R2, G2, and B2”, in accordance with the 3D LUT before the modification.

In this case, when the desired color “R2, G2, and B2” also exists at a grid point of the 3D LUT, the corresponding CMYK values “C2, M2, Y2, and K2” can be immediately determined.

On the other hand, when the desired color “R2, G2, and B2” does not exist at a grid point of the 3D LUT, appropriate interpolation processing is performed based on CMYK values located at, for example, eight grid points that are adjacent to the desired color “R2, G2, and B2” to determine the CMYK values “C2, M2, Y2, and K2”.

The CMYK values “C2, M2, Y2, and K2” determined in such a manner are replaced with the CMYK values “C1, M1, Y1, and K1” that exist at a grid point of the color “R1, G1, and B1” before the modification, to thereby modify the 3D LUT.

On the other hand, when the color “R1, G1, and B1” that the user desires to modify does not exist at a grid point of the 3D LUT, for example, eight grid points “R11, G11, and B11”, “R12, G12, and B12”, . . . , and “R18, G18, and B18” that are immediately adjacent to the color “R1, G1, and B1” are extracted and the CMYK values of 3D LUT data which correspond to the respective eight extracted grid points are modified.

The CMYK values “C2, M2, Y2, and K2” corresponding to the desired color “R2, G2, and B2” are determined in accordance with the 3D LUT before the modification.

Next, CMYK values “C1i, M1i, Y1i, and K1i” (i=1 to 8) corresponding to the eight grid points “R1i, G1i, and B1i” (i=1 to 8) are replaced with values “C2i, M2i, Y2i, and K2i” (i=1 to 8), respectively, to thereby modify the 3D LUT. In this case, values “C2i, M2i, Y2i, and K2i” (i=1 to 8) are determined so that CMYK values determined by interpolation calculation using the values “C2i, M2i, Y2i, and K2i” (i=1 to 8) become desired values “C2, M2, Y2, and K2”.

The 3D LUT (i.e., the color conversion parameter) modified as described above is stored by the color-conversion-parameter storing means 150.

When the color conversion parameter is modified and the document data shown in FIG. 4A is then re-input via the inputting means 110, color conversion processing is performed in accordance with the modified color conversion parameter, so that the red of character data 1 is printed in red desired by the user.

According to the image processing apparatus 1 of the first embodiment, the color adjusting means 170 can readily display a document to present the document to the user, regardless of the format of input document data. Also, since the same picture as the input document data is displayed, the user can easily and promptly designate color that he or she desires to modify (i.e., pre-modification color).

In addition, desired colors contained in a hardcopy document in the possession of the user can be displayed side by side by the read-image displaying means 172, so as to allow the desired colors (i.e., pre-modification color) to be easily designated with the color instructing means (the X-shaped cursor 173b).

The present embodiment is merely one example of the present invention. Thus, the color conversion processing parameters, the items designated and design of the color adjusting means 170 can be changed within the scope and spirit of the present invention, and the present invention does not exclude such changes.

### (2) Second Embodiment

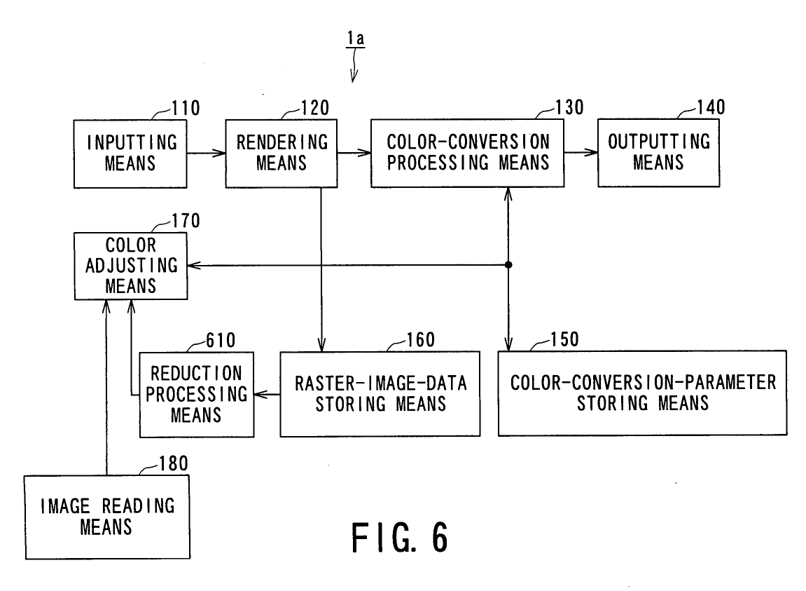

FIG. 6 shows an exemplary configuration of an image processing apparatus 1a according to a second embodiment of the present invention. The image processing apparatus 1a of the second embodiment has a configuration in which reduction processing means 610 is added to the image processing apparatus 1 of the first embodiment.

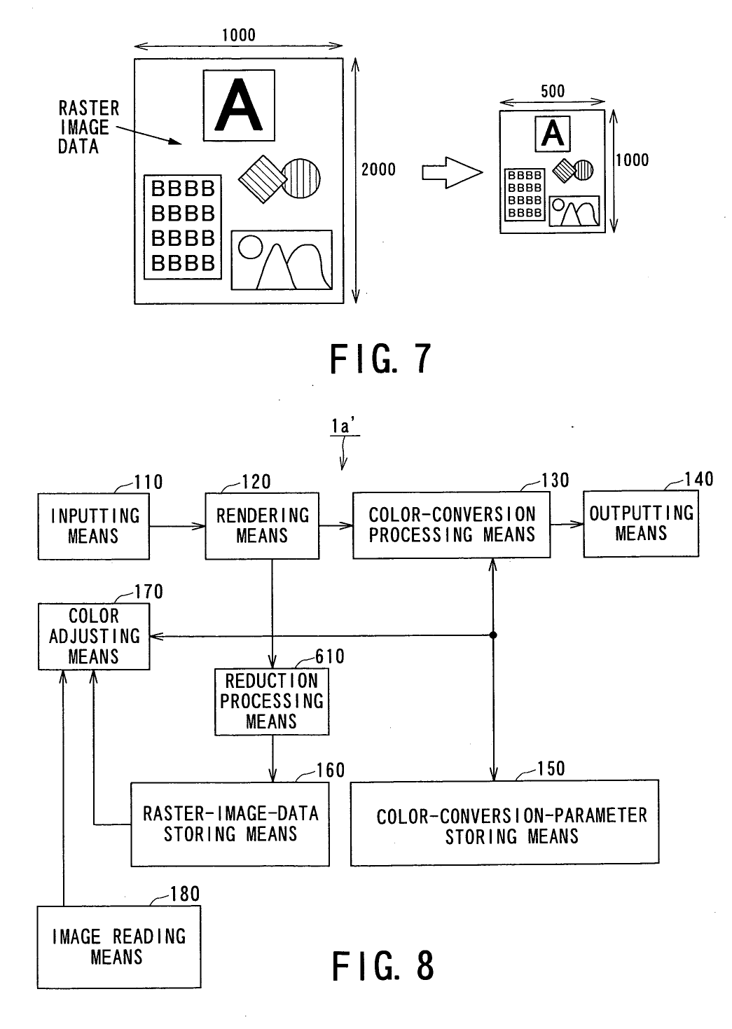

The reduction processing means 610 has a function for reducing the size of raster image data stored by the raster-image-data storing means 160, i.e., a function for reducing the number of pixels in the vertical and horizontal directions. For example, as show in FIG. 7, the reduction processing means 610 converts the pixels of 2000 height×1000 width of raster image data into the pixels of 1000 height×500 width.

Raster image data output from the rendering means 120 has a data size corresponding to the output resolution of the outputting means 140. However, since the color adjusting means 170 does not necessarily require high-resolution raster image data to display an image, a reduction in the size of raster image data does not cause any problem in many cases.

As shown in FIG. 8, the same advantages can be provided even when the reduction processing means 610 is provided before the raster image data generated by the rendering means 120 is stored by the raster-image-data storing means 160.

The operation of the present embodiment is analogous to that of the first embodiment except that a raster image whose data size is reduced by the reduction processing means 610 is displayed on the screen of the color adjusting means 170.

In addition to the advantages of the image processing apparatus 1 of the first embodiment, the image processing apparatus 1a of the second embodiment provides advantages in that the image-display speed is increased and the image-display memory is reduced since the provision of the reduction processing means 610 reduces the size of raster image data.

### (3) Third Embodiment

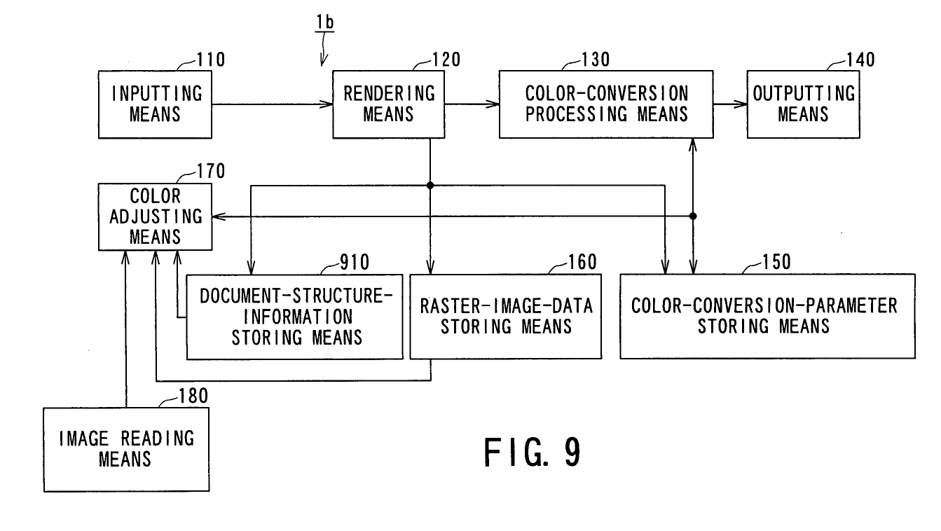

FIG. 9 shows an exemplary configuration of an image processing apparatus 1b according to a third embodiment of the present invention.

The image processing apparatus 1b of the third embodiment has a configuration in which document-structure-information storing means 910 is added to the image processing apparatus 1 of the first embodiment.

The document structure information used herein includes information regarding objects in document data, information (i.e., output-condition instruction information) regarding conditions for output by outputting means, or both pieces of the information.

The information regarding objects in document data includes information regarding the type of object contained in document data and information indicating which object exists at which position in the document. The information (i.e., output-condition instruction information) regarding conditions for output by the outputting means includes information, such as the resolution of an output image, the type of halftone, and the type of print paper for a case of printing.

The rendering means 120 converts input document data into raster image data, identifies an object type (e.g., a character, graphics, or nature picture) in the document data, and further generates document structure information from the identified object type. As shown in FIG. 2C, the document structure information includes information indicating which object exists at which position in the document.

In accordance with the result of the identification of the object type in the document data, the rendering means 120 designates a color conversion parameter corresponding to the identified object, from multiple color conversion parameters stored by the color-conversion-parameter storing means 150.

The color-conversion processing means 130 converts the color of raster image data in accordance with the color conversion parameter. The color conversion parameter used in this case is expressed by a color conversion table corresponding to the object type identified by the rendering means 120. The color-conversion processing means 130 can perform color conversion according to the above-described method.

The color-conversion-parameter storing means 150 stores multiple color conversion parameters that are used by the color-conversion processing means 130 and that correspond to object types.

The document-structure-information storing means 910 stores the document structure information generated by the rendering means 120.

The color adjusting means 170 modifies a color conversion parameter stored by the color-conversion-parameter storing means 150 so that desired color is output in accordance with a user instruction. The color conversion parameter used in this case is selected based on the document structure information stored by the document-structure-information storing means 910.

A specific example of operation of the image processing apparatus 1b according to the third embodiment will be described below.

FIG. 4A shows one-page document data that the user has created using typical document creation software. This document data contains character data, vector (graphics) data, and nature image data. The character of document data 1 is, for example, a red character that the user designated using the typical document creation software. The document data is input to the image processing apparatus 1b via the inputting means 110.

Subsequently, the rendering means 120 converts all of the character data, vector data, and nature image data in the document into RGB raster image data shown in FIG. 4B. The rendering means 120 generates document structure information indicating which object is located at which position in the document data, as shown in FIG. 4D. The document structure information is stored by the document-structure-information storing means 910. The raster image data is stored by the raster-image-data storing means 160 and is also input to the color-conversion processing means 130.

Of 3D LUT data that contains color conversion parameters stored by the color-conversion-parameter storing means 150, 3D LUT data corresponding to the object type identified by the rendering means 120 is set for the color-conversion processing means 130. Subsequently, based on the 3D LUT, the color-conversion processing means 130 sequentially performs interpolation calculation on input RGB raster image data, to convert the image data into CMYK values, as required. FIG. 4C shows raster image data color-converted into CMYK as described above. The raster image data color-converted into CMYK values is printed by the outputting means 140.

When the user sees a printed hard copy, he or she may think that the red of the character of character data 1 is not desired color. In such a case, using the color adjusting means 170, the user can adjust a color conversion parameter for the character object so that desired red is obtained for the character of character data 1.

An example of color adjustment using the color adjusting means 170 in the present embodiment will now be described in more detail. As in the first embodiment, the color adjusting means 170 has user interfaces, for example, the image displaying means 171 and 172 and the color instructing means 173a and 173b, as illustrated in FIG. 5. The image displaying means 171 displays raster image data. The read-image displaying means 172 displays read raster image data.

When the raster image data displayed by the image displaying means 171 contains color that the user desires to modify (i.e., pre-modification color), he or she uses the color instructing means (i.e., the crosshair cursor 173a) to designate the color that he or she desires to modify.

The image displaying means 171 displays raster image data stored by the raster-image-data storing means 160. In this case, the format of the raster image data has already been converted into a raster data format by the rendering means 120. Thus, the image display means 171 can easily display the RGB raster image data, without a need for a special format converter. The user uses a pointing device (not shown), such as a mouse, to point the crosshair cursor 173a to the portion of character data 1 on the raster image displayed by the image displaying means 171. With this operation, the color of character data 1 is designated as unwanted color, that is, color to be modified (i.e., pre-modification color). The RGB values of the color of character data 1 at this point are stored by the color adjusting means 170 as “R1, G1, and B1”.

Next, the user uses the X-shaped cursor 173b to select desired color (a color patch) from the read raster image data displayed by the read-image displaying means 172. In response to the operation, the color of character data 1 displayed by the image displaying means 171 changes. However, the color of a portion which is different from the original color “R1, G1, and B1” of character data 1 does not change.

With the operation described above, the user can designate the color of character data 1 so that it becomes desired red. The RGB values of the color of character data 1 are stored by the color adjusting means 170 as “R2, G2, and B2”.

After the color “R1, G1, and B1” that the user desires to modify and the desired color “R2, G2, and B2” are designated, the color conversion parameter is modified in accordance with the designation. The method for modifying the color conversion parameter is analogous to the method described in the first embodiment.

The color conversion parameter to be modified in the present embodiment is determined in accordance with the document structure information. Thus, the color adjusting means 170 compares the position of the color that the user has designated, with the crosshair cursor 173a using the color instructing means of the color adjusting means 170, with the document structure information stored by the document-structure-information storing means 910. As a result, the color adjusting means 170 recognizes which type of object includes the color that the user has designated with the crosshair cursor 173a using the color instructing means. Based on the result of the recognition, the color adjusting means 170 selects a color conversion parameter corresponding to the object type, from color conversion parameters stored by the color-conversion-parameter storing means 150. Since the user gives an instruction for modifying the color of character data 1, the selected color conversion parameter corresponds to the character object.

After the color conversion parameter is modified, when the document data shown in FIG. 4A is input again via the inputting means 110, color conversion is performed in accordance with the modified color conversion parameter. Thus, the red of character data 1 is printed in red desired by the user. Also, since the modified color conversion parameter corresponds to only the character object, the color of other objects, i.e., the graphics object and the nature image object, does not change.

According to the image processing apparatus 1b of the third embodiment, in addition to the advantages of the image processing apparatus 1 of the first embodiment, a color conversion parameter to be modified is automatically selected based on the document structure information and, when the user gives an instruction for designating a portion containing color to be modified and desired color therefor, the color conversion parameter is automatically modified. Moreover, since only a color conversion parameter corresponding to the type of object containing the color designated by the user is modified, the color of other objects which does not require any modification is not affected.

Although the above description has been given of a case in which the type of object in the document data is used as the document structure information, for example, print-output conditions, such as a paper type or a halftone type specified by the document data, may be used as the document structure information and both of the type of object in the document data and the print-output conditions may also be used as the document structure information.

### (4) Fourth Embodiment

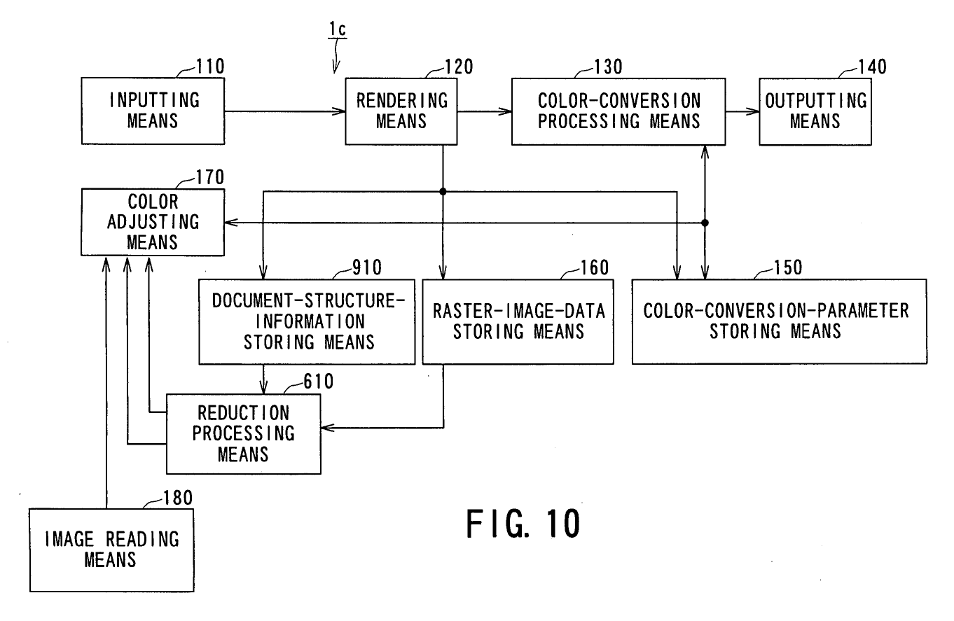

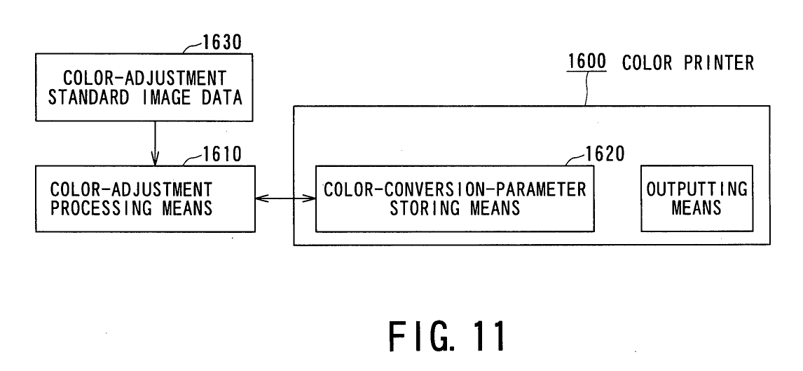

FIG. 10 shows an exemplary configuration of an image processing apparatus 1c according to a fourth embodiment of the present invention.

The image processing apparatus 1c of the fourth embodiment has a configuration in which reduction processing means 610 is added to the image processing apparatus 1b of the third embodiment.

As in the second embodiment, the reduction processing means 610 reduces the size of raster image data stored by the raster-image-data storing means 160. In addition, the reduction processing means 610 reduces the size of document structure information (i.e., the size of a document structure layout) stored by the document-structure-information storing means 910 so as to correspond to the reduced size of the raster image data.

The raster image data may be reduced before being stored by the raster-image-data storing means 160.

In addition to the advantages of the image processing apparatus 1 of the first embodiment, the fourth embodiment can achieve the advantages of the image processing apparatus 1a of the second embodiment and the image processing apparatus 1b of the third embodiment.

The present invention is not merely limited to the specific embodiments described above, and changes and modifications are also possible to the elements disclosed in the embodiments within the spirit and scope of the present invention. The elements of the embodiments may be appropriately combined to achieve various modifications. For example, some of the elements shown in the embodiments may be eliminated. In addition, some of the elements used in different embodiments may be appropriately combined.

What is claimed is:

1. An image processing apparatus comprising:
inputting means for inputting document data;
rendering means for generating raster image data from the input document data;
color-conversion-parameter storing means for storing a color conversion parameter;
color-conversion processing means for performing color conversion on the raster image data in accordance with the color conversion parameter;
outputting means for outputting the raster image data color-converted by the color-conversion processing means;
reading means for reading a color image to generate read raster image data;
displaying means for displaying the raster image data generated by the rendering means and the read raster image data; and
color adjusting means for adjusting color of the output raster image data by modifying the color conversion parameter, with color of a portion designated on a screen displayed by the displaying means being color to be modified.

2. The image processing apparatus according to claim 1, further comprising reduction processing means for reducing the raster image data generated by the rendering means,
wherein the displaying means displays the reduced raster image data and the read raster image data.

3. The image processing apparatus according to claim 1, wherein the color adjusting means comprises color instructing means for designating desired color in accordance with color of the read raster image data and adjusts the color to be modified to the designated desired color.

4. The image processing apparatus according to claim 1, further comprising reduction processing means for reducing the raster image data generated by the rendering means,
wherein the displaying means displays the reduced raster image data and the read raster image data, and the color adjusting means comprises color instructing means for designating desired color in accordance with the read raster image data and performs adjustment so that the color to be modified becomes the designated desired color.

5. The image processing apparatus according to claim 1, further comprising document-structure-information storing means for storing document structure information generated by the rendering means,
wherein the color-conversion processing means performs color conversion on the raster image data in accordance with a color conversion parameter corresponding to the document structure information, and the color adjusting means adjusts color of the output raster image data by modifying the color conversion parameter corresponding to the document structure information, with color of a portion designated on a screen displayed by the displaying means being color to be modified.

6. The image processing apparatus according to claim 5, further comprising reduction processing means for reducing the raster image data and the document structure information generated by the rendering means,
wherein the reading means generates read raster image data having a size corresponding to the reduction processing, and the displaying means displays the reduced raster image data and the read raster image data.

7. The image processing apparatus according to claim 5, wherein the color adjusting means comprises color instructing means for designating desired color in accordance with color of the read raster image data and performs adjustment so that the color to be modified becomes the designated desired color.

8. The image processing apparatus according to claim 5, further comprising:
reduction processing means for reducing the raster image data and the document structure information generated by the rendering means,
wherein the reading means generates read raster image data having a size corresponding to the reduction processing, the displaying means displays the reduced raster image data and the read raster image data, and the color adjusting means comprises color instructing means for designating desired color in accordance with color of the red raster image data and performs adjustment so that the color to be modified becomes the designated desired color.

9. The image processing apparatus according to claim 5, wherein the document structure information includes at least one of type information of an object contained in the document data and output-condition instruction information contained in the document data.

10. An image processing method, comprising the steps of:
inputting document data;
generating raster image data from the input document data;
storing a color conversion parameter;
performing color conversion on the raster image data in accordance with the color conversion parameter;
outputting the color-converted raster image data;
reading a color image to generate read raster image data;
displaying the generated raster image data and the read raster image data; and
adjusting color of the output raster image data by modifying the color conversion parameter corresponding to the document structure information, with color of a designated portion of the displayed raster image data being color to be modified.

11. The image processing method according to claim 10, further comprising a step of reducing the generated raster image data,
wherein the reduced raster image data and the read raster image data are displayed in the displaying step.

12. The image processing method according to claim 10, wherein in the color adjusting step, desired color is designated in accordance with the read raster image data and the color to be modified is adjusted to the designated desired color.

13. The image processing method according to claim 10, further comprising a step of reducing the generated raster image data,
wherein in the displaying step, the reduced raster image data and the read raster image data are displayed, and in the color adjusting step, desired color is designated in accordance with color of the read raster image data and adjustment is performed so that the color to be modified becomes the designated desired color.

14. The image processing method according to claim 10, further comprising a step of generating document structure information from the document data and a step of storing the generated document structure information;
wherein in the color conversion step, the raster image data is color-converted in accordance with a color conversion parameter corresponding to the document structure information; and in the color adjusting step, color of the output raster image data is adjusted by modifying the color conversion parameter corresponding to the document structure information, with color of a designated portion of the displayed raster image data being color to be modified.

15. The image processing method according to claim 14, further comprising a step of reducing the generated raster image data and the document structure information,
wherein the reduced raster image data and the read raster image data are displayed in the displaying step.

16. The image processing method according to claim 14, wherein in the color adjusting step, desired color is designated in accordance with color of the read raster image data and the color to be modified is adjusted to the designated desired color.

17. The image processing method according to claim 14, further comprising a step of reducing the generated raster image data and the document structure information,
wherein in the displaying step, the reduced raster image data and the read raster image data are displayed and, in the color adjusting step, desired color is designated in accordance with color of the read raster image data and adjustment is performed so that the color to be modified becomes the designated desired color.

18. The image processing method according to claim 14, wherein the document structure information includes at least one of type information of an object contained in the document data and output-condition instruction information contained in the document data.
